(19) United States
(12) Patent Application Publication
(10) Pub. No.: US 2014/0225655 A1
(43) Pub. Date: Aug. 14, 2014

(54) CLOCK-GATED SYNCHRONIZER

(71) Applicant: QUALCOMM INCORPORATED, San Diego, CA (US)

(72) Inventors: Seid Hadi Rasouli, San Diego, CA (US); Animesh Datta, San Diego, CA (US); Ohsang Kwon, San Diego, CA (US)

(73) Assignee: QUALCOMM Incorporated, San Diego, CA (US)

(21) Appl. No.: 13/767,729

(22) Filed: Feb. 14, 2013

(51) Int. Cl. H03L 7/00

(52) U.S. Cl. CPC H03L 7/00
USPC 327/161; 327/141

(57) ABSTRACT

Techniques for clock gating a synchronizer are described herein. In one embodiment a circuit for clock gating a synchronizer comprises a clock-gating circuit configured to receive an input clock signal, and to selectively provide either the input clock signal or a fixed clock signal to the synchronizer. The circuit also comprises a comparator configured to compare a data value of a data signal input to the synchronizer, a first value of the synchronizer, and a second value of the synchronizer with one another, to instruct the clock-gating circuit to provide the input clock signal to the synchronizer if the data value, the first value, and the second value are not all the same, and to instruct the clock-gating circuit to provide the fixed clock signal to the synchronizer if the data value, the first value, and the second value are all the same.

### BACKGROUND

1. Field

Aspects of the present disclosure relate generally to synchronizers, and more particularly, to clock-gated synchronizers.

2. Background

Two different blocks in a device may operate at different clock frequencies. As a result, when one of the blocks (a sender block) sends a data signal to the other block (a receiver block), the data signal is asynchronous with respect to the receiver block. In this regard, the receiver block may include a synchronizer to synchronize the incoming data signal with a clock of the receiver block. The synchronizer may do this by capturing data values of the data signal on the rising and/or falling edges of the receiver clock.

The synchronizer may include a plurality of switching elements that switch at twice the frequency of the receiver clock in order to capture the value of the data signal at the frequency of the receiver clock. Switching the switching elements consumes power, which negatively impacts the battery life of a mobile device that includes the synchronizer.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

According to an aspect, a circuit for clock gating a synchronizer is described herein. The circuit comprises a clock-gating circuit configured to receive an input clock signal, and to selectively provide either the input clock signal or a fixed clock signal to the synchronizer. The circuit also comprises a comparator configured to compare a data value of a data signal input to the synchronizer, a first value of the synchronizer, and a second value of the synchronizer with one another, to instruct the clock-gating circuit to provide the input clock signal to the synchronizer if the data value, the first value, and the second value are not all the same, and to instruct the clock-gating circuit to provide the fixed clock signal to the synchronizer if the data value, the first value, and the second value are all the same.

A second aspect relates to a method for clock gating a synchronizer. The method comprises comparing a data value of a data signal input to the synchronizer, a first value of the synchronizer, and a second value of the synchronizer with one another. The method also comprises passing an input clock signal to the synchronizer if the data value, the first value, and the second value are not all the same, and outputting a fixed clock signal to the synchronizer if the data value, the first value, and the second value are all the same.

A third aspect relates to an apparatus for clock gating a synchronizer. The apparatus comprises means for comparing a data value of a data signal input to the synchronizer, a first value of the synchronizer, and a second value of the synchronizer with one another. The apparatus also comprises means for passing an input clock signal to the synchronizer if the data value, the first value, and the second value are not all the same, and means for outputting a fixed clock signal to the synchronizer if the data value, the first value, and the second value are all the same.

To the accomplishment of the foregoing and related ends, the one or more embodiments comprise the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 shows a system that includes a sender block and a receiver block.

FIG. 2 shows a synchronizer that includes two flip-flops coupled in series.

FIG. 3 shows a synchronizer with clock gating according to an embodiment of the present disclosure.

FIG. 4 shows an exemplary implementation of the synchronizer in FIG. 3 using logic gates according to an embodiment of the present disclosure.

FIG. 5 shows an example of a timing diagram for the synchronizer in FIG. 4 according to an embodiment of the present disclosure.

FIG. 6 shows an example of a timing diagram for a synchronizer that only compares the output of the synchronizer with an input data signal.

FIG. 7 shows a synchronizer with a latch according to an embodiment of the present disclosure.

FIG. 8 shows an exemplary implementation of the synchronizer in FIG. 7 using logic gates according to an embodiment of the present disclosure.

FIG. 9 shows an example of a timing diagram for the synchronizer in FIG. 8 according to an embodiment of the present disclosure.

FIG. 10 shows an exemplary implementation of a synchronizer with clock gating according to an embodiment of the present disclosure.

FIG. 11 shows a latch according an embodiment of the present disclosure.

FIG. 12 is a flowchart illustrating a method for clock gating a synchronizer according to certain embodiments of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

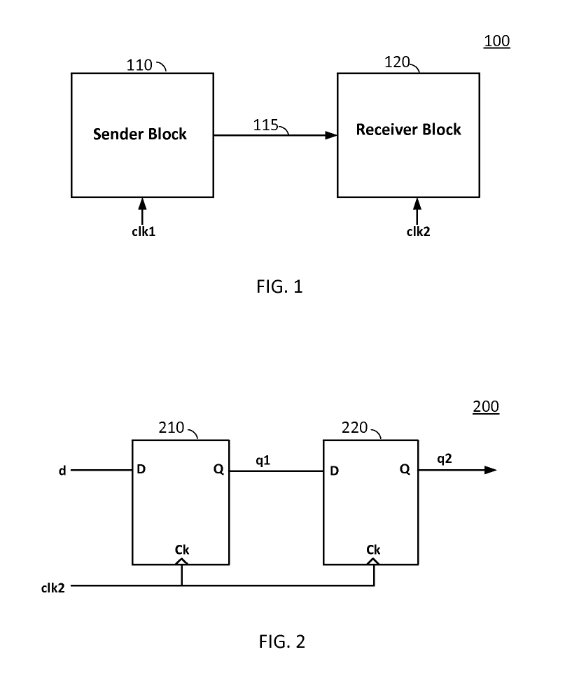

FIG. 1 shows an example of a system 100 comprising a sender block 110 and a receiver block 120, in which the sender block 110 sends a data signal to the receiver block 120 over a transmission medium 115 (e.g., a bus, a transmission line, etc.). For example, the sender block 110 may comprise a memory block and the receiver block 120 may comprise a processor, in which the memory block sends data read from memory to the processor for processing. The sender block 110 and the receiver block 120 may be integrated on the same chip (same die) or may be on separate chips.

The sender block 110 may operate according to a first clock signal clk1, and the receiver block 120 may operate according to a second clock signal clk2, in which the first and second clock signals clk1 and clk2 have different frequencies. Because of the different clock frequencies, the data signal from the sender block 110 is asynchronous with respect to the receiver block 120. In this regard, the receiver block 120 may include a synchronizer that synchronizes the incoming data signal from the sender block 110 with the second clock signal clk2 of the receiver block 120.

FIG. 2 shows an example of a synchronizer 200 that may be included in the receiver block 120 to synchronize the data signal from the sender block 110 with the second clock signal clk2 of the receiver block 120. The synchronizer 200 comprises a first-stage D flip-flop 210 and a second-stage D flip-flop 220 coupled in series.

In operation, the data signal from the sender block 110 is input to the first-stage D flip-flop 210. The first-stage D flip-flop 210 captures a data value of the data signal on a rising or falling edge of the second clock signal clk2, and outputs the captured data value q1 to the second-stage D flip-flop 220 until the next rising or falling edge of the second clock signal clk2. The second-stage D flip-flop 220 captures the data value q1 output from the first-stage D flip-flop 210 on a rising or falling edge of the second clock signal clk2, and outputs the captured data value q2 until the next rising or falling edge of the second clock signal clk2.

Each D flip-flop 210 and 220 may include a plurality of switching elements (e.g., transistors) that switch at twice the frequency of the second clock signal clk2 in order to capture the value of the data signal at the frequency of the second clock signal clk2. Switching the switching elements consumes power, which negatively impacts the battery life of a mobile device that includes the synchronizer 200. According it is desirable to reduce switching of the switching elements to reduce power consumption, and extend the battery life of the mobile device.

In some applications, the sender block 110 may operate at a much lower clock frequency than the receiver block 120 (e.g., 1000 times slower), in which case, the data signal from the sender block 110 changes at a much lower frequency than the frequency of the second clock signal clk2. As a result, the value of the data signal remains constant over many clock cycles (periods) of the second clock signal clk2, and therefore does not need to be captured at each cycle of the second clock signal clk2. However, the synchronizer 200 may continue to capture the value of the data signal at the frequency of the second clock signal clk2 regardless of whether the value of the data signal changes, thereby consuming power unnecessarily.

Accordingly, it is desirable to gate the second clock signal clk2 so that the second clock signal clk2 is fixed when the value of the data signal does not change. This substantially reduces switching activity in the flip-flops 210 and 220 when the data signal does not change over multiple cycles of the second clock signal clk2, thereby reducing power consumption and increasing the battery life of the mobile device.

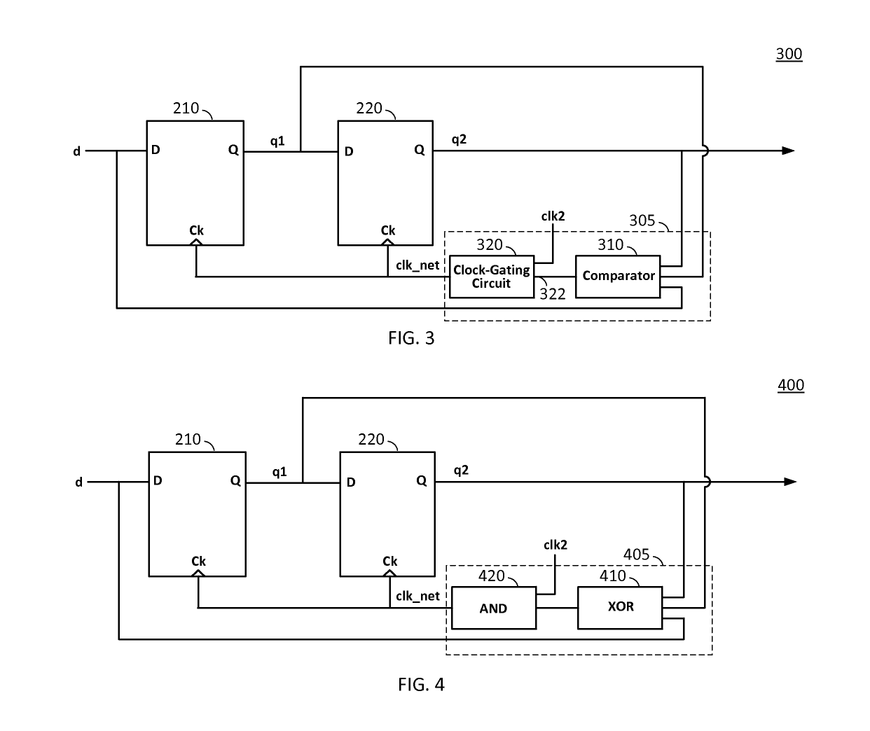

FIG. 3 shows a synchronizer 300 with clock gating in accordance with an embodiment of the present disclosure. The synchronizer 300 comprises a circuit 305 for gating the second clock signal clk2. The circuit 305 includes a comparator 310, and a clock-gating circuit 320.

The clock-gating circuit 320 gates the second clock signal clk2 based on a command received at a control input 322. The command may instruct the clock-gating circuit 320 to pass the second clock signal clk2 to the flip-flops 210 and 220 as clock signal clk_net or instruct the clock-gating circuit 320 to fix the value of the clock signal clk_net to the flip-flops 210 and 220 regardless of changes in the second clock signal clk2. When the clock signal clk_net is fixed, switching of the switching elements in the flip-flops 210 and 220 is disabled, thereby conserving power. The clock-gating circuit 320 is controlled by the comparator 310, as discussed further below.

The comparator 310 compares the value of the input data signal d, the value at the output q1 of the first flip-flop 210, and the value at the output q2 of the second flip-flop 220 with one another. If all three values are the same, then the comparator 310 instructs the clock-gating circuit 320 to fix the clock signal clk_net to the flip-flops 210 and 220. This disables switching in the flip-flops 210 and 220, thereby conserving power. Otherwise, the comparator 310 instructs the clock-gating circuit 240 to pass the second clock signal clk2 to the flip-flops 210 and 220 as the clock signal clk_net. In this case, switching in the flip-flops 210 and 220 is enabled.

Thus, the comparator 310 fixes the clock signal clk_net to the flips-flops 210 and 220 when the value of the input data signal d, the value at the output q1 of the first flip-flop 210, and the value at the output q2 of the second flip-flop 220 are all the same. After the clock signal clk_net is fixed, the comparator 310 may keep the clock signal clk_net fixed as long as the value of the input data signal d, the value at the output q1 of the first flip-flop 210, and the value at the output q2 of the second flip-flop 220 remain the same. Thus, when the value of the input data signal d does not change from the output values of the flip-flops 210 and 220, and therefore does not need to be recaptured, switching in the flips-flops 210 and 220 is disabled to conserve power.

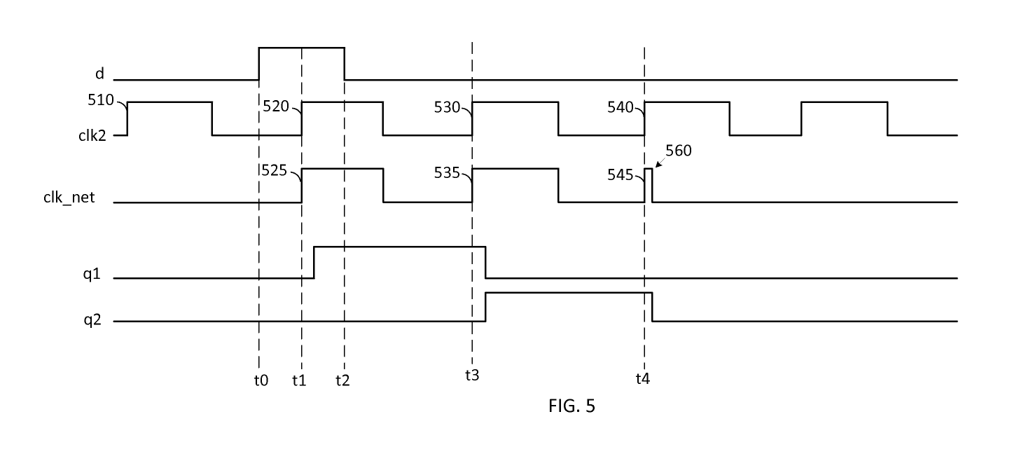

FIG. 4 shows a synchronizer 400, in which the circuit 305 in FIG. 3 is implemented using logic gates. In this example, the circuit 405 for gating the second clock signal clk2 comprises an Exclusive OR (XOR) gate 410 that implements the comparator 310, and an AND gate 420 that implements the clock-gating circuit 320.

The input data signal d, the output q1 of the first flip-flop 210, and the output q2 of the second flip-flop 220 are input to the XOR gate 410. When the values of all three inputs are the same, the XOR gate 410 outputs a zero. Otherwise, the XOR gate 410 outputs a one.

The second clock signal clk2 and the output of the XOR gate 410 are input to the AND gate 420. The clock signal clk_net to the flip-flops 210 and 220 is taken from the output of the AND gate 420. When the output of the XOR gate 410 is zero, the output of the AND gate 420 is fixed at zero regardless of the value of the second clock signal clk2. Thus, when the value of the input data signal d, the value at the output q1 of the first flip-flop 210, and the value at the output q2 of the second flip-flop 220 are all the same, the AND gate 420 fixes the clock signal clk_net at zero.

When the output of the XOR gate 410 is one, the output of the AND gate 420 follows the value of the second clock signal clk2. Thus, when the value of the input data signal d, the value at the output q1 of the first flip-flop 210, and the value at the output q2 of the second flip-flop 220 are not all the same, the AND gate 420 passes the second clock signal clk2 to the flip-flops 210 and 220 as the clock signal clk_net.

It should be appreciated that embodiments of the present disclosure may be implemented using other combinations of logic gates, and are therefore not limited to the example shown in FIG. 4.

Thus, the synchronizers 300 and 400 in FIGS. 3 and 4 conserve power by disabling switching in the flip-flips 210 and 220 when the data signal does not change over multiple cycles of the second clock signal clk2 (e.g., when the input data signal has a lower frequency than the second clock signal clk2). The synchronizers 300 and 400 are also able to properly capture the value of a data signal having a frequency at or near the frequency of the second clock clk2. This may be demonstrated by way of the following example.

FIG. 5 shows a timing diagram for the synchronizer 400, in which the value of the data signal changes for one clock cycle of the second clock signal ck2. The timing diagram includes the data signal (denoted d), the second clock signal clk2, the clock signal clk_net to the flip-flops 210 and 220, the output value q1 of the first flip-flop 210, and the output value q2 of the second flip-flip 220.

Initially, the data signal, the output value q1 of the first flip-flop 210, and the output value q2 of the second flip-flip 220 are all zero. As a result, the clock signal clk_net is initially fixed at zero by the AND gate 420, and therefore does not rise with the first rising edge 510 of the second clock signal clk2 shown in FIG. 5.

At time t0, the value of the data signal changes from zero to one. This causes the output of the XOR gate 410 to become one, which, in turn, causes the output of the AND gate 420 (i.e., the clock signal clk_net) to follow the second clock signal clk2. As a result, the clock signal clk_net rises with the second rising edge 520 of the second clock signal clk2 at time t1. For ease of discussion, the short delay between rising edges of the clock signals is neglected.

At time t1, the first flip-flop 210 captures the value of the data signal on the rising edge 525 of the clock signal clk_net. In this example, the captured value is one. After a short delay, the captured value of one appears at the output q1 of the first flip-flop 210. The short delay is due to internal delays in the first flip-flop 210. At about this time, the previous value (zero) at the output q1 of the first flip-flop 210 is transferred to the second flip-flip 220.

At time t2, the value of the data signal changes from one back to zero. The output of the XOR gate 410 remains one because the output value q1 of the first flip-flop 210 is one, which differs from the value of the data signal (now zero) and the output value q2 of the second flip-flop 220. As a result, the clock signal clk_net continues to follow the second clock signal clk2, and therefore rises with the third rising edge 530 of the second clock signal clk2.

At time t3, the first flip-flop 210 captures the current value of the input data signal (zero) on the rising edge 535 of the clock signal clk_net. After a short delay, the captured value of zero appears at the output q1 of the first flip-flop 210. At about this time, the previous value (one) at the output q1 of the first flip-flop 210 is transferred to the second flip-flip 220, causing the output value of the second flip-flop 220 to change from zero to one.

The output of the XOR gate 410 remains one because the output value q2 of the second flip-flop 220 is one, which differs from the value of the data signal and the output value q1 of the first flip-flop 210. As a result, the clock signal clk_net continues to follow the second clock signal clk2, and therefore rises with the fourth rising edge 540 of the second clock signal clk2.

At time t4, the previous value (zero) at the output q1 of the first flip-flop 210 is transferred to the second flip-flop 220 on the rising edge 545 of the clock signal clk_net. After a short delay, the output value q2 of the second flip-flop 220 changes from one to zero.

When this occurs, the value of the data signal, the output value q1 of the first flip-flop 210, and the output q2 value of the second flip-flop 220 are all zero. This causes the output of the XOR gate 410 to change from one to zero. As a result, the AND gate 420 fixes the clock signal clk_net to zero, causing the clock signal clk_net to transition from one to zero.

Thus, the synchronizer 400 is able to properly capture and output a value of the data signal that changes at or near the frequency of the second clock signal clk2. This is because the synchronizer 400 compares the output values of both flip-flops 210 and 220 with the value of the data signal in making a determination whether to disable switching in the flip-flops 210 and 220. Therefore, the synchronizer 400 is able to synchronize data signals having a wide range of frequencies including frequencies much lower than the second clock signal clk2 and frequencies at or near the frequency of the second clock signal clk2. This may not be possible for a synchronizer that only compares the output value of the synchronizer with the value of the data signal, which may be demonstrated by way of the following example.

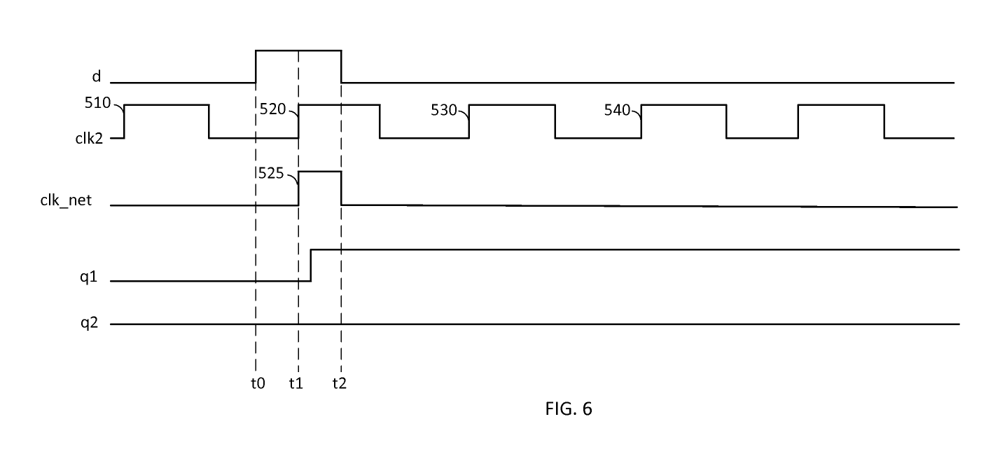

FIG. 6 shows a timing diagram for a synchronizer that only inputs the output value of the synchronizer (output value q2 of the second flip-flop 220) and the value of the data signal to the XOR gate 410. The output value q1 of the first flip-flop 210 is not input to the XOR gate 410. For comparison reasons, the data signal and the second clock signal clk2 in FIG. 6 are the same as in the timing diagram in FIG. 5.

Initially, the data signal and the output value q2 of the second flip-flip 220 are both zero. As a result, the clock signal clk_net is initially fixed at zero by the AND gate 420, and therefore does not rise with the first rising edge 510 of the second clock signal clk2.

At time t0, the value of the data signal changes from zero to one. This causes the output of the XOR gate 410 to become one, which, in turn, causes the output of the AND gate 420 (i.e., the clock signal clk_net) to follow the second clock signal clk2. As a result, the clock signal clk_net rises with the second rising edge 520 of the second clock signal clk2 at time t1.

At time t1, the first flip-flop 210 captures the value of the data signal on the rising edge 525 of the clock signal clk_net. In this example, the captured value is one. After a short delay, the captured value of one appears at the output q1 of the first flip-flop 210. The short delay is due to internal delays in the first flip-flop 210. At about this time, the previous value (zero) at the output q1 of the first flip-flop 210 is transferred to the second flip-flip 220.

At time t2, the value of the input data signal changes from one back to zero. The output of the XOR gate 410 also changes from one back to zero. This is because the output value of the synchronizer (output value q2 of the second flip-flop 220) and the data signal are both zero. As a result, the clock signal clk_net is fixed at zero, and switching in the first and second flip-flops 210 and 220 is disabled.

Because switching is disabled in the flip-flops 210 and 220, the output value q1 (one) of the first flip-flop 210 is not transferred to the second flip-flop 220 on the third rising edge 530 of the second clock signal clk2. The output value q1 of the first flip-flop 210 stays at one, and the output value q2 of the second flip-flop 220 stays at zero. Thus, the captured value of one is trapped in the first flip-flop 210, and does not propagate out of the synchronizer. Embodiments of the present disclosure prevent this from happening by inputting the output values of both flip-flops to the XOR gate 410 in addition to the data signal. This allows the value in the first flip-flop 210 to propagate to the second flip-flop 220 and out of the synchronizer, as shown in FIG. 5.

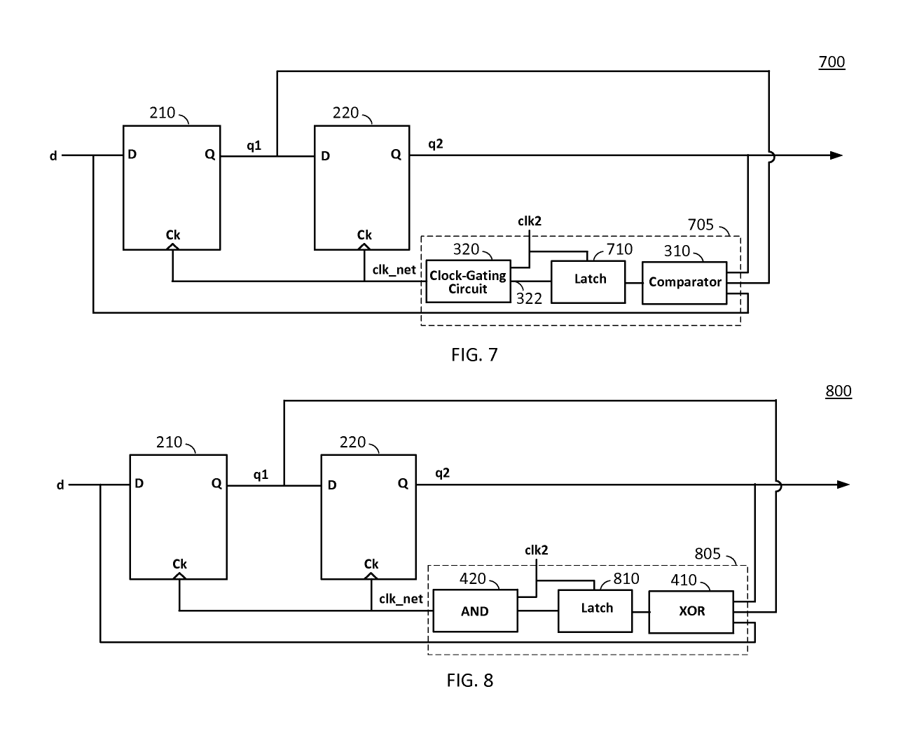

FIG. 7 shows a synchronizer 700 according to another embodiment of the present disclosure. The synchronizer 700 is similar to the synchronizer 300 in FIG. 3, in which the circuit 705 for gating the second clock signal clk2 further comprises a latch 710 coupled between the comparator 310 and the clock-gating circuit 320.

The latch 710 receives the second clock signal clk2 and the output of the comparator 310. When the comparator 310 outputs an instruction to the clock-gating circuit 320 to fix the clock signal clk_net to the flip-flops 210 and 220, the latch 710 determines whether the current value of the second clock signal clk2 is the same as the fixed value of the clock signal clk_net. If they are the same, then the latch 710 passes the instruction to the clock-gating circuit 320. If they are not the same, then the latch 710 delays sending the instruction to the clock-gating circuit 320 until the second clock signal clk2 transitions to a value equal to the fixed value of the clock signal clk_net. This may be done to prevent the creation of an asynchronous pulse in the clock signal clk_net, as discussed further below.

FIG. 8 shows a synchronizer 800 according to another embodiment of the present disclosure. The synchronizer 800 is similar to the synchronizer 400 in FIG. 4, in which the circuit 805 for gating the second clock signal clk2 further comprises a latch 810 coupled between the XOR gate 410 and the AND gate 420.

The latch 810 receives the second clock signal clk2 and the output of the XOR gate 410. As discussed above, the XOR gate 410 outputs a zero to cause the AND gate 420 to fix the clock signal clk_net to a value of zero. In this embodiment, when the XOR gate 410 outputs a zero, the latch 810 determines whether the current value of the second clock signal clk2 is zero (i.e., the same as the fixed value of the clock signal clk_net when switching is disabled). If the current value of the second clock signal clk2 is zero, then the latch 810 passes the zero output value from the XOR gate 410 to the AND gate 420. If the current value of the second clock signal clk2 is one, then the latch 810 delays passing the zero output value from the XOR gate 410 to the AND gate 420 until the second clock signal clk2 transitions from one to zero.

The latches 710 and 810 may be used to prevent the creation of an asynchronous pulse in the clock signal clk_net, which may cause asynchronous switching in the synchronizer and lead to an unpredictable state in the synchronizer. This may be demonstrated by way of the following examples.

The timing diagram in FIG. 5 shows a short asynchronous pulse 560 in the clock signal clk_net when there is no latch. The short pulse 560 is created because the output of the XOR gate 410 transitions from one to zero when zero appears at the output q2 of the second flip-flip 220, which occurs after a short delay from the rising edge 545 of the clock signal clk_net. The transition of the output of the XOR gate 420 from one to zero causes the output of the AND gate 420 (i.e., the clock signal clk_net) to transition from one to zero. As a result, the clock signal clk_net transitions from one to zero, creating the short asynchronous pulse 560 in FIG. 5. The pulse 560 is asynchronous with respect to the second clock signal clk2 because the transition from one to zero is not synchronized with an edge of the second clock signal clk2. In general, the XOR gate 420 may transition from one to zero at any time (e.g., due to the asynchronous nature of the data signal), which may result in the creation of an asynchronous pulse in the clock signal clk_net.

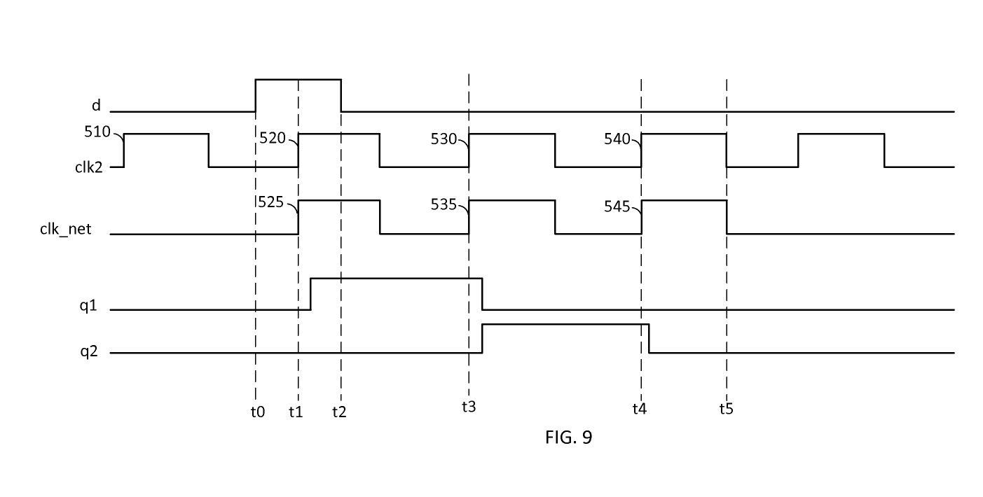

The latches 710 and 810 prevent the creation of the asynchronous pulse 560 shown in FIG. 5. This can be explained with reference to FIG. 9, which shows a timing diagram similar to the one in FIG. 5 with the addition of the latch 810. Shortly after time t4, a zero appears at the output q2 of the second flip-flop 220. This causes the XOR gate 410 to transition from one to zero since all three inputs to the XOR gate 410 are now zero. When the XOR gate 410 transitions from one to zero, the value of the second clock signal clk2 is one, which is different from zero (the fixed value of the clock signal clk_net when switching is disabled). Because the second clock signal clk2 is one, the latch 810 does not pass the zero output value of the XOR gate 410 to the AND gate 420 at this time. Instead, the latch 810 continues to output a one to the AND gate 420, allowing the clock signal clk_net to continue following the second clock signal clk2.

At time t5, the second clock signal clk2 transitions from one to zero. At this time, the latch 810 passes the zero output value of the XOR gate 410 to the AND gate 420. This causes the AND gate 420 to fixed the clock signal clk_net at zero. Thus, the latch 810 delays passing the zero output value of the XOR gate 410 until the second clock signal clk2 transitions from one to zero. This eliminates the asynchronous pulse 560 shown in FIG. 5 without the latch 810.

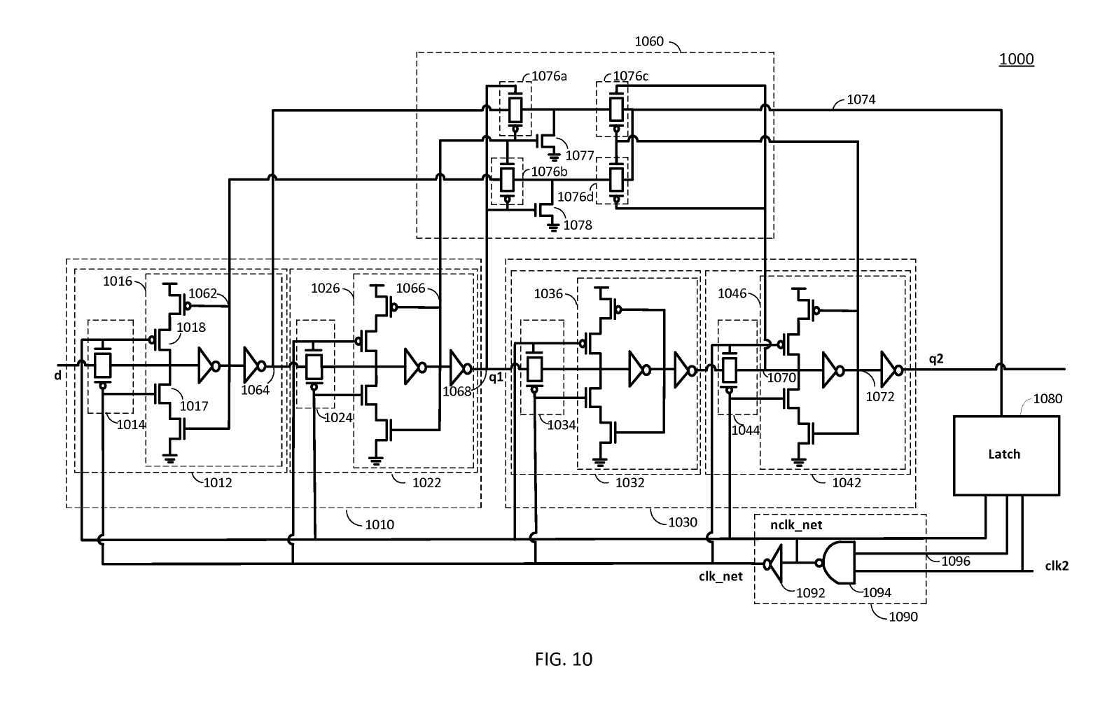

FIG. 10 shows an exemplary implementation of a synchronizer with clock gating according to an embodiment of the present disclosure. The synchronizer 1000 comprises a first-stage D flip-flop 1010 and a second-stage D flip-flop 1030 coupled in series. The flip-flops 1010 and 1030 receive the clock signal clk_net and its compliment (logical inverse) nclk_net to perform switching in the flip-flops 1010 and 1030, as discussed further below.

The first-stage D flip-flop 1010 includes a master latch 1012 and a slave latch 1022 coupled in series. The master latch 1012 includes a first transmission gate 1014 and a first storage circuit 1016, and the slave latch 1022 includes a second transmission gate 1024 and a second storage circuit 1026. The first transmission gate 1014 is configured to pass the input data signal when the clock signal clk_net is zero, and to block the input data signal when the clock signal clk_net is one. The second transmission gate 1024 is configured to pass the output of the master latch 1012 when the clock signal clk_net is one, and to block the output of the master latch 1012 when the clock signal clk_net is zero.

Operation of the first flip-flop 1010 will now be described for the case in which the clock signal clk_net follows the second clock signal clk2. When the clock signal clk_net is zero, the first transmission gate 1014 passes the input data signal to the first storage circuit 1016, and therefore allows the data signal to enter the master latch 1012. When the clock signal clk_net transitions from zero to one, the first storage circuit 1016 stores the value of the input data signal on the rising edge of the clock signal clk_net, and outputs the stored value to the slave latch 1022 while the clock signal clk_net is one. At about this time, the first transmission gate 1014 blocks the input data signal, thereby isolating the first storage circuit 1016 from the input data signal while the clock signal clk_net is one. Thus, the master latch 1012 captures (latches) the value of the input data signal on the rising edge of the clock signal clk_net, and outputs the captured value to the slave latch 1022 while the clock signal clk_net is one.

When the clock signal clk_net is one, the second transmission gate 1024 passes the captured data value output from the master latch 1012. As a result, the second transmission gate 1024 transfers the data value captured by the master latch 1012 to the second storage circuit 1026 of the slave latch 1022, and the second storage circuit 1026 outputs the data value captured by the master latch 1012.

When the clock signal clk_net transitions from one back to zero, the second transmission gate 1024 blocks the output of the master latch 1012, thereby isolating the second storage circuit 1026 from the master latch 1012 while the clock signal clk_net is zero. The second storage circuit 1026 stores the captured data value transferred to the second storage circuit 1026 from the master latch 1012, and continues to output the captured data value until the next rising edge of the clock signal clk_net. At the next rising edge of the clock signal clk_net, the above operations are repeated.

Thus, the first-stage D flip-flop 1010 captures a value of the data signal on the rising edge of the clock signal clk_net, and outputs the captured data value until the next rising edge of the clock signal clk_net (i.e., outputs the captured data value for one clock period).

The second-stage D flip-flop 1030 captures the data value q1 output from the first-stage D flip-flop 1010 on a rising edge of the clock signal clk_net, and outputs the captured data value q2 until the next rising edge of the clock signal. Similar to the first-stage D flip-flop 1010, the second-stage D flip-flop 1030 includes a master latch 1032 and a slave latch 1042. The master latch 1032 includes a first transmission gate 1034 and a first storage circuit 1036, and the slave latch 1042 includes a second transmission gate 1044 and a second storage circuit 1046. The second-stage D flip-flop 1030 operates in a similar manner as the first-stage D flip-flop 1010, and therefore a detailed description of the second-stage D flip-flop 1030 is omitted here for sake of brevity.

The synchronizer 1000 has numerous switching elements that switch at twice the frequency of the second clock signal clk2. For example, each of the transmission gates 1014, 1024, 1034 and 1044 includes two switching elements. More particularly, each transmission gate includes an N-type metal-oxide-semiconductor (NMOS) transistor and a P-type metal-oxide-semiconductor (PMOS) transistor coupled in parallel. The NMOS transistor and the PMOS transistor pass a signal through the respective transmission gate when switched on, and block a signal from passing through the respective transmission gate when switched off. The NMOS transistor and the PMOS transistor may be switched on and off during each cycle of the second clock signal clk2.

Further, each storage circuit 1016, 1026, 1036 and 1046 includes at least two switching elements. For example, the storage circuit 1016 includes an NMOS transistor 1017 and a PMOS transistor 1018 that act as switching elements. When the NMOS transistor 1017 and the PMOS transistor 1018 are switched on, the storage circuit 1016 stores (holds) the data value currently in the storage circuit 1016. Each of the other storage circuits may have similar switching elements.

Switching of these switching elements consumes power, which reduces the battery life of a mobile device that includes the synchronizer 1000. Therefore, it is desirable to gate the second clock signal clk2 to disable switching of the switching elements in the flip-flops 1010 and 1030 when the value of the data signal does not change over multiple cycles of the second clock signal clk2.

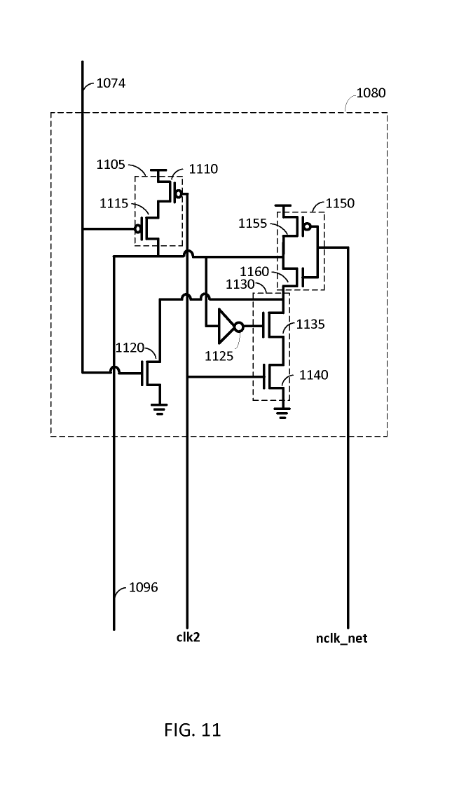

To this end, the synchronizer 1000 further comprises a comparator 1060, a latch 1080, and a clock-gating circuit 1090. The latch 1080 is shown in more detail in FIG. 11 according to one embodiment.

The clock-gating circuit 1090 comprises a NAND gate 1094 and an inverter 1092 coupled in series. The NAND gate 1094 has a first input coupled to a gate-control input 1096 and a second input coupled to the second clock signal clk2. The inverter 1092 has an input coupled to the output of the NAND gate 1094 and an output that outputs the clock signal clk_net to the flip-flops 1010 and 1030. The compliment (logical inverse) of the clock signal clk_net (denoted nclk_net) is output from the NAND gate 1094.

When the gate-control input 1096 is one, the NAND gate 1094 acts as an inverter coupled in series with the inverter 1092. As a result, the clock signal clk_net follows the second clock signal clk2. When the gate-control input 1096 is zero, the output of the NAND gate 1094 is one regardless of the value of the second clock signal clk2. As a result, the value of the clock signal clk_net (which is taken from the output of the inverter 1092) is fixed at zero.

When the clock signal clk_net is fixed at zero, the data value in the second storage element 1026 of the first-stage D flip-flop 1010 is stored (held) as long as the clock signal clk_net is fixed at zero. This is because, without switching, a new data value is not transferred to the second storage element 1026. Similarly, the data value in the second storage element 1046 of the second-stage D flip-flop 1030 is stored (held) as long as the clock signal clk_net is fixed at zero. Thus, when the clock signal clk_net is fixed at zero, the data values in the flip-flops 1010 and 1030 stay the same and are not updated. When the data signal is constant over multiple cycles of the second clock signal clk2, the data values in the flip-flops 1010 and 1030 do not need to be updated, and therefore power can be conserved by fixing the clock signal clk_net at zero.

Gating by the clock-gating circuit 1090 may be controlled by the comparator 1060. The comparator 1060 compares the value of the data signal d, the value at the output q1 of the first flip-flop 1010, and the value at the output q2 of the second flip-flop 1030 with one another. If all three values are the same, then the comparator 1060 instructs the clock-gating circuit 1090 to fix the clock signal clk_net. Otherwise, the comparator 1060 instructs the clock-gating circuit 1090 to pass the second clock signal clk2 as the clock signal clk_net to the flip-flops 1010 and 1030.

To determine the value of the data signal, the comparator 1060 samples the values at nodes 1062 and 1064 in the master latch 1012 of the first flip-flop 1010. When the clock signal clk_net is zero, the transmission gate 1014 allows the data signal to enter the master latch 1012. This allows the value of the data signal to be determined from the values at nodes 1062 and 1064 in the master latch 1012. In this example, the value at node 1062 is the logical inverse of the value of the data signal, and the value at node 1064 follows the value of the data signal. Thus, the comparator 1060 need not be directly connected to the input of the first flip-flop 1010 to determine the value of the data signal. The comparator 1060 can determine the value of the data signal by tapping one or more internal nodes in the master latch 1012.

To determine the value at the output q1 of the first flip-flop 1010, the comparator 1060 samples the values at node 1066 in the slave latch 1022 of the first flip-flop 1010, and node 1068 at the output q1 of the first flip-flop 1010. The value at node 1066 is the logical inverse of the value at the output q1 of the first flip-flop 1010.

Thus, the comparator 1060 may determine the value at the output q1 of the first flip-flop 1010 by tapping the output q1 of the first flip-flop 1010 directly and/or tapping one or more node in the slave latch 1022 of the first flip-flop 1010. In the example shown in FIG. 10, the comparator 1060 directly taps the output q1 of the first flip-flop 1010 at node 1068 and taps node 1066 in the slave latch 1022 of the first flip-flop 1010.

To determine the value at the output q2 of the second flip-flop 1030, the comparator 1060 samples the values at nodes 1070 and 1072 in the slave latch 1042 of the second flip-flop 1030. The value at node 1070 follows the value at the output q2 of the second flip-flop 1030, and the value at node 1072 is the logical inverse of the value at the output q2 of the first flip-flop 1030.

The comparator 1060 comprises a plurality of transmission gates 1076a-1076d, a first shorting NMOS transistor 1077, and a second shorting NMOS transistor 1078. The transmission gates 1076a and 1076b are controlled by the values sampled at nodes 1066 and 1068 of the first flip-flop 1010, and the transmission gates 1076c and 1076d are controlled by the values sampled at nodes 1070 and 1072 of the second flip-flop 1030. The transmission gates 1076a-1076d control whether the value at node 1062 or the value at node 1064 in the master latch 1012 of the first flip-flop 1010 is passed to the output 1074 of the comparator 1060.

The first shorting NMOS transistor 1077 selectively shorts the path between transmission gates 1076a and 1076c to ground, and is controlled by the value at node 1066 of the first flip-flop 1010. The second shorting NMOS transistor 1078 selectively shorts the path between transmission gates 1076b and 1076d to ground, and is controlled by the value at node 1068 of the first flip-flop 1010.

In operation, the transmission gates 1076a-1076d and the shorting transistors 1077 and 1078 cooperate to perform the functions of the comparator 1060 described herein. The comparator 1060 outputs a one when the value of the data signal d, the value at the output q1 of the first flip-flop 1010, and the value at the output q2 of the second flip-flop 1030 are all the same. Otherwise the comparator 1060 output a zero.

The output 1074 of the comparator 1060 may be inverted and coupled to the gate-control input 1096 of the clock-gating circuit 1090 to control the clock-gating circuit 1090. Thus, when the value of the data signal d, the value at the output q1 of the first flip-flop 1010, and the value at the output q2 of the second flip-flop 1030 are all the same, the gate-control input 1096 is zero, causing the clock-gating circuit 1090 to fix the clock signal clk_net at zero.

In the example shown in FIG. 10, the comparator output 1074 is coupled to the gate-control input 1096 of the clock-gating circuit 1090 through the latch 1080. The latch 1080 may be an inverting latch 1080. The latch 1080 receives the second clock signal clk2 and the comparator output 1074. When the comparator output 1074 transitions from zero to one, the latch 1080 determines whether the second clock signal clk2 is zero. If the second clock signal clk2 is zero, then the latch 1080 inverts the comparator output 1074 and passes the inverted comparator output (zero) to the gate-control input 1096 to fix the clock signal clk_net. If the second clock signal clk2 is one, then the latch 1080 delays passing the inverted comparator output (zero) to the gate-control input 1096 until the second clock signal clk2 transitions from one to zero.

FIG. 11 shows an implementation of the latch 1080 according to an embodiment of the present disclosure. The latch 1080 comprises a PMOS stack 1105 that includes a first PMOS transistor 1110 and a second PMOS transistor 1115, and an NMOS stack 1130 that includes a first NMOS transistor 1135 and a second NMOS transistor 1140. The latch 1080 also comprises a third NMOS transistor 1120, an inverter 1125, and a CMOS inverter 1150 that includes a third PMOS transistor 1155 and a fourth NMOS transistor 1160.

The gates of the second PMOS transistor 1115 and the third NMOS transistor 1120 are driven by the comparator output 1074, and the gates of the first PMOS transistor 1110 and the second NMOS transistor 1140 are driven by the second clock signal clk2. The gates of the third PMOS transistor 1155 and the fourth NMOS transistor 1160 are driven by the inverse clock signal nclk_net. The gate of the first NMOS transistor 1135 is driven by the inverter 1125.

In operation, when the comparator output 1074 transitions from zero to one, the second PMOS transistor 1115 is turned off and the third NMOS transistor 1120 is turned on. If the second clock signal clk2 is one, then the first PMOS transistor 1110 is turned off and the second NMOS transistor 1140 is turned on. In addition, the third PMOS transistor 1155 is turned on and the fourth NMOS transistor 1160 is turned off. The third PMOS transistor 1155 (which is on) pulls the gate-control input 1096 up to one. Thus, if the second clock signal clk2 is one when the comparator output 1074 transitions from zero to one, then the latch 1080 maintains the gate-control input 1096 at one at this time.

If the second clock signal clk2 is zero, then the first PMOS transistor 1110 is turned on and the second NMOS transistor 1140 is turned off. In addition, the third PMOS transistor 1155 is turned off and the fourth NMOS transistor 1160 is turned on. The third NMOS transistor 1120 (which is on) and the fourth NMOS transistor 1160 (which is on) pull down the gate-control input 1096 to ground (zero). Thus, if the second clock signal clk2 is initially one when the comparator output 1074 transitions from zero to one, then the latch 1080 transitions the gate-control input 1096 from one to zero when the second clock signal clk2 transitions to one to zero. The zero value of the gate-control input 1096 causes the clock-gating circuit 1090 to fix the clock signal clk_net at zero.

Thus, if the second clock signal clk2 is one when the comparator output 1074 transitions from zero to one, then the latch 1080 delays fixing the clock signal clk_net until the second clock signal clk2 transitions from one to zero. As discussed above, this prevents the creation of an asynchronous pulse in the clock signal clk_net. If the second clock signal clk2 is already zero when the comparator output 1074 transitions from zero to one, then the latch 1080 does not delay fixing the clock signal clk_net.

When the comparator output 1074 is zero, the latch 1080 outputs a value of one for the gate-control input 1096 to enable switching regardless of the value of the second clock signal clk2.

Although embodiments of the present disclosure are described above using the example of a positive-edge-triggered synchronizer, it is to be appreciated that embodiments of the present disclosure are not limited to this example and can be applied to a negative-edge-triggered synchronizer.

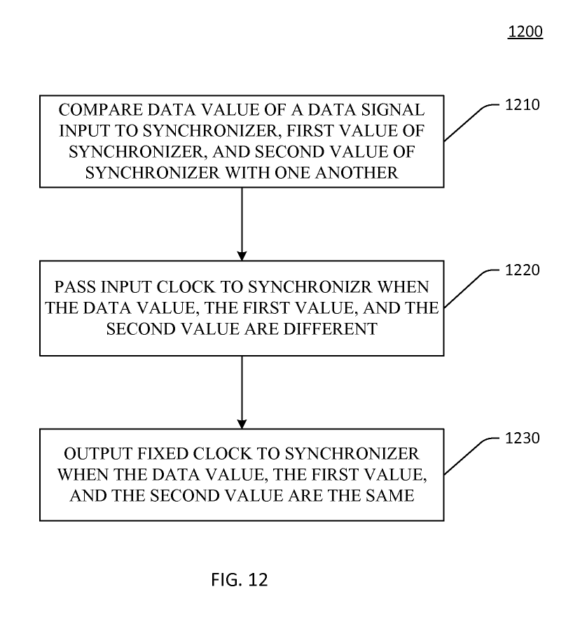

FIG. 12 is a flow diagram of a method 1200 for clock gating a synchronizer in accordance with embodiments of the present disclosure.

In step 1210, a data value of a data signal input to the synchronizer, a first value of the synchronizer, and a second value of the synchronizer are compared with one another. For example, the synchronizer may include a first flip-flop (e.g., the first flip-flop 210) and a second flip-flop (e.g., the second flip-flop 220) coupled in series, in which the first value is an output value of the first flip-flop, and the second value is an output value of the second flip-flop.

In step 1220, an input clock signal is passed to the synchronizer if the data value, the first value, and the second value are not all the same. For example, a comparator (e.g., the comparator 310) may instruct a clock-gating circuit (e.g., the clock-gating circuit 320) to pass the input clock signal (e.g., the second clock signal clk2) to the synchronizer if the data value, the first value, and the second value are not all the same.

In step 1230, a fixed clock signal is output to the synchronizer if the data value, the first value, and the second value are all the same. For example, a comparator (e.g., the comparator 310) may instruct a clock-gating circuit (e.g., the clock-gating circuit 320) to output a fixed clock signal to the synchronizer if the data value, the first value and the second value are all the same. The fixed clock signal may disable switching in the synchronizer to conserve power.

Those skilled in the art would appreciate that the circuits described herein may be realized using a variety of transistor types, and are therefore not limited to the particular transistor types shown in the figures. For example, transistor types such as bipolar junction transistors, junction field effect transistor or any other transistor type may be used. Those skilled in the art would also appreciate that the circuits described herein may be fabricated with various IC process technologies such as CMOS, bipolar junction transistor (BJT), bipolar-CMOS (BiCMOS), silicon germanium (SiGe), gallium arsenide (GaAs), etc.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A circuit for clock gating a synchronizer, comprising:
a clock-gating circuit configured to receive an input clock signal, and to selectively provide either the input clock signal or a fixed clock signal to the synchronizer; and
a comparator configured to compare a data value of a data signal input to the synchronizer, a first value of the synchronizer, and a second value of the synchronizer with one another, to instruct the clock-gating circuit to provide the input clock signal to the synchronizer if the data value, the first value, and the second value are not all the same, and to instruct the clock-gating circuit to provide the fixed clock signal to the synchronizer if the data value, the first value, and the second value are all the same.

2. The circuit of claim 1, wherein the synchronizer comprises a first flip-flop and a second flip-flip coupled in series, the first value is an output value of the first flip-flop, and the second value is an output value of the second flip-flop.

3. The circuit of claim 2, wherein the first flip-flop comprises a master latch and a slave latch coupled in series, and the comparator determines the output value of the first flip-flop based on a value at a node in the slave latch.

4. The circuit of claim 3, wherein the comparator determines the data value based on a value at a node in the master latch.

5. The circuit of claim 1, further comprising a latch coupled between the comparator and the clock-gating circuit, wherein the latch is configured to delay an instruction from the comparator to the clock-gating circuit to output the fixed clock signal when the input clock signal has a value that is different from a value of the fixed clock signal.

6. The circuit of claim 5, wherein the latch is configured to delay the instruction to output the fixed clock signal until the input clock signal transitions to a value that is equal to the value of the fixed clock signal.

7. The circuit of claim 5, wherein the value of the fixed clock signal is zero.

8. The circuit of claim 7, wherein the latch is configured to delay the instruction to output the fixed clock signal until the input clock signal transitions from a value of one to a value of zero.

9. A method for clock gating a synchronizer, comprising:
comparing a data value of a data signal input to the synchronizer, a first value of the synchronizer, and a second value of the synchronizer with one another;
passing an input clock signal to the synchronizer if the data value, the first value, and the second value are not all the same; and
outputting a fixed clock signal to the synchronizer if the data value, the first value, and the second value are all the same.

10. The method of claim 9, wherein the synchronizer comprises a first flip-flop and a second flip-flip coupled in series, the first value is an output value of the first flip-flop, and the second value is an output value of the second flip-flop.

11. The method of claim 10, wherein the first flip-flop comprises a master latch and a slave latch coupled in series, and further comprising determining the output value of the first flip-flop based on a value at a node in the slave latch.

12. The method of claim 11, further comprising determining the data value based on a value at a node in the master latch.

13. The method of claim 9, further comprising delaying outputting the fixed clock signal when the input clock signal has a value that is different from a value of the fixed clock signal.

14. The method of claim 13, wherein delaying outputting the fixed clock signal comprises delaying outputting the fixed clock signal until the input clock signal transitions to a value that is equal to the value of the fixed clock signal.

15. The method of claim 13, wherein the value of the fixed clock signal is zero.

16. The method of claim 15, wherein delaying outputting the fixed clock signal comprises delaying outputting the fixed clock signal until the input clock signal transitions from a value of one to a value of zero.

17. An apparatus for clock gating a synchronizer, comprising:
means for comparing a data value of a data signal input to the synchronizer, a first value of the synchronizer, and a second value of the synchronizer with one another;
means for passing an input clock signal to the synchronizer if the data value, the first value, and the second value are not all the same; and
means for outputting a fixed clock signal to the synchronizer if the data value, the first value, and the second value are all the same.

18. The apparatus of claim 17, wherein the synchronizer comprises a first flip-flop and a second flip-flip coupled in series, the first value is an output value of the first flip-flop, and the second value is an output value of the second flip-flop.

19. The apparatus of claim 18, wherein the first flip-flop comprises a master latch and a slave latch coupled in series, and further comprising means for determining the output value of the first flip-flop based on a value at a node in the slave latch.

20. The apparatus of claim 19, further comprising means for determining the data value based on a value at a node in the master latch.

21. The apparatus of claim 17, further comprising means for delaying outputting the fixed clock signal when the input clock signal has a value that is different from a value of the fixed clock signal.

22. The apparatus of claim 21, wherein the means for delaying outputting the fixed clock signal comprises means for delaying outputting the fixed clock signal until the input clock signal transitions to a value that is equal to the value of the fixed clock signal.

23. The apparatus of claim 21, wherein the value of the fixed clock signal is zero.

24. The apparatus of claim 23, wherein the means for delaying outputting the fixed clock signal comprises means for delaying outputting the fixed clock signal until the input clock signal transitions from a value of one to a value of zero.
